(19) United States
(12) Patent Application Publication
(10) Pub. No.: US 2026/0090443 A1
(43) Pub. Date: Mar. 26, 2026

(54) POWER SEMICONDUCTOR DEVICES WITH BOND PADS HAVING STRUCTURAL SUPPORT LAYERS

(71) Applicant: Wolfspeed, Inc., Durham, NC (US)

(72) Inventors: Sneha Pandya, Apex, NC (US); Thomas Harrington, Durham, NC (US); Daniel Richter, Raleigh, NC (US)

(21) Appl. No.: 18/893,188

(22) Filed: Sep. 23, 2024

(51) Int. Cl. H01L 23/00; H01L 29/16

(52) U.S. Cl. CPC H10W 72/90; H10D 62/8325; H10W 72/923; H10W 72/952

(57) ABSTRACT

A semiconductor device includes a semiconductor die, and a bond pad on the semiconductor die, the bond pad comprising a bond layer, and a structural support layer between the bond layer and the semiconductor die. The bond layer has a first hardness and the structural support layer has a second hardness that is greater than the first hardness. A semiconductor device according to some embodiments includes a semiconductor die, and a bond pad on the semiconductor die. The bond pad includes a seed layer and two or more support/bond layer pairs on the seed layer, wherein each support/bond layer pair includes a structural support layer and a bond layer on the structural support layer. Each bond layer in a support/bond layer pair has a first hardness and each structural support layer in a support/bond layer pair has a second hardness that is greater than the first hardness.

### FIELD

The present disclosure relates to semiconductor power devices, and in particular to metallizations for power semiconductor devices.

### BACKGROUND

Power semiconductor devices typically have relatively thin topside and backside metallizations. This is the result of a number of factors, including metal deposition process capabilities, process time and cost, and stress induced warpage of the wafer. For high current power devices, however, these thin metallization layers introduce limitations to performance and reliability of the product. This is particularly so for wide band gap devices which offer considerably higher potential current densities. These higher densities require advancements in the devices and their associated packages to achieve their full potential.

The presence of thin layers may limit performance and reliability at both the device and package levels. For example, at the device level, thin metal layers may result in high current concentrations, uneven current distribution, localized heating and/or localized thermal stresses. At the package level, thin metal layers may result in limitations in the power interconnection size (wire diameter, ribbon thickness, etc.), limitations in the power interconnection material (softer materials vs. harder materials), a higher risk of device damage during wire/ribbon bonding, localized thermal stresses at the interconnection interface and/or limiting the allowable current (i.e. the device is not fully utilized).

Thicker metallization, particularly on the topside metal layer, may help address these issues on multiple fronts. For example, the use of thicker metallization (particularly top side metallization) may allow buffering the current to a more even distribution, and/or may reduce the localized heating and spreading it away from critical interfaces. Additionally, the use of thicker metallization may help to improve robustness for larger size power interconnections and/or may provide a capability to apply compatible materials for different power interconnection materials.

Creating the thicker metallization on a semiconductor wafer, however, has challenges which limit to what is practical and possible. Wafers are relatively thin at the time of processing, and may encounter multiple high temperature conditions as the devices are formed. Thicker metal layers, particularly if only on one side, can introduce warpage and distortion that are often too high for usage.

### SUMMARY

A semiconductor device according to some embodiments includes a semiconductor die, and a bond pad on the semiconductor die, the bond pad comprising a bond layer, and a structural support layer between the bond layer and the semiconductor die. The bond layer has a first hardness and the structural support layer has a second hardness that is greater than the first hardness.

In some embodiments, the bond pad includes a barrier layer, wherein the structural support layer is between the barrier layer and the bond layer, and a first metal layer, wherein the barrier layer is on the first metal layer between the first metal layer and the bond layer. The first metal layer includes a metal having a third hardness that is less than the second hardness.

The structural support layer may have a thickness and contacts the first metal layer over a footprint of the structural support layer. The thickness and second hardness of the structural support layer are selected to distribute a force applied to the bond layer during attachment of a wire bond to the bond layer across the footprint of the structural support layer on the first metal layer.

The semiconductor device may further include a seed layer on the barrier layer, wherein the seed layer is between the barrier layer and the structural support layer.

The seed layer may be the same metal as the bond layer.

The bond layer may include copper, and the structural support layer may include a metal having a greater hardness than copper.

The structural support layer may include nickel, tungsten, platinum, titanium, tantalum, TiN, and/or TaN.

The structural support layer may have a thickness of between about 1 micron and 5 microns, in some embodiments between about 1.5 microns and 3 microns, and in some embodiments about 2 microns.

The bond layer may be a first bond layer, and the semiconductor device may further include a second bond layer between the structural support layer and the barrier layer.

The structural support layer may be a first structural support layer, and the semiconductor device may further include a second structural support layer. The second structural support layer is between the second bond layer and the barrier layer. The second structural support layer has a third hardness that is greater than the first hardness.

In some embodiments, the semiconductor device may include a metal stack including a plurality of pairs of bond layers and structural support layers, wherein a top layer of the metal stack comprises one of the bond layers of the plurality of bond layers.

The semiconductor die may include silicon carbide, and the bond layer and the structural support layer may be electroplated layers.

A semiconductor device according to some embodiments includes a semiconductor die, and a bond pad on the semiconductor die. The bond pad includes a seed layer, a first bond layer on the seed layer, a structural support layer on the first bond layer, and a second bond layer on the structural support layer. The bond layer has a first hardness and the structural support layer has a second hardness that is greater than the first hardness.

The semiconductor device may further include a second structural support layer between the seed layer and the first bond layer. The second structural support layer has a third hardness that is greater than the first hardness.

The first and second bond layers comprise copper and the structural support layer may include nickel, tungsten, platinum, titanium, manganese, TiN, and/or TaN.

The bond pad may include a first metal layer, wherein the seed layer is between the first metal layer and the bond layer.

A semiconductor device according to some embodiments includes a semiconductor die, and a bond pad on the semiconductor die. The bond pad includes a seed layer, and two or more support/bond layer pairs on the seed layer, wherein each support/bond layer pair includes a structural support layer and a bond layer on the structural support layer. Each bond layer in a support/bond layer pair has a first hardness and each structural support layer in a support/bond layer pair has a second hardness that is greater than the first hardness.

Each bond layer may include copper and each structural support layer may include nickel, tungsten, platinum, titanium, tantalum, TiN, and/or TaN.

The semiconductor device may further include a barrier layer, wherein the seed layer is between the barrier layer and the plurality of support/bond layer pairs.

The bond pad may include a first metal layer, wherein the seed layer is between the first metal layer and the bond layer.

### BRIEF DESCRIPTION OF THE DRAWINGS

FIG. 1 illustrates an example of a MOSFET device.

FIG. 2 illustrates an example of a MOSFET circuit.

FIGS. 3, 4A and 4B illustrate cross-sectional views of MOSFET devices including a plurality of MOSFET cells.

FIG. 5 illustrates a metal stack on a semiconductor device.

FIG. 6 illustrates formation of a wire bond on a metal stack on a semiconductor device.

FIG. 7 illustrates a detail of an end portion of a metal stack of a semiconductor device.

FIG. 8 illustrates a detail of an end portion of a metal stack of a semiconductor device according to some embodiments.

FIG. 9 illustrates a detail of an end portion of a metal stack of a semiconductor device according to further embodiments.

FIG. 10 illustrates a detail of an end portion of a metal stack of a semiconductor device according to further embodiments.

### DETAILED DESCRIPTION OF EMBODIMENTS

Wide Band Gap power devices, including devices based on silicon carbide (SIC), gallium nitride (GaN), and the like offer a high level of performance benefits, including high voltage blocking, low on-resistance, high current, fast switching, low switching losses, high junction temperatures, and high thermal conductivity. Ultimately, these characteristics result in a notable increase in potential power density, which is power processed per area or volume.

Achieving this potential, however, requires addressing significant challenges at the package and system level. The higher voltages, currents, and switching speeds manifest into significantly higher physical stresses applied onto smaller and more constrained areas. To fully take advantage of what SiC technology has to offer, several challenges must be addressed both at the device and the package level, including the formation of electrical interconnections from the device topsides to the package substrate or terminals. Other challenges include waste heat removal, including conduction and switching losses from the devices, and effective electrical isolation between high voltage potentials. Wide bandgap power devices should also have the capability to handle high steady state currents, capability to handle high transient current events, mechanical robustness to reliably operate in high stress, high temperature, high vibration environments. Such devices should be compatible with advanced interconnection materials, structures, and techniques, as well as with advanced device attach materials, structures, and techniques.

Power packages contain power semiconductor devices, including MOSFETs, JFETs, IGBTs, diodes, and the like, arranged into a variety of circuit topologies. A device package serves many functions, including electrical interconnection, electrical isolation, heat transfer, and mechanical structure. The package protects devices from environmental contamination and moisture, and provides external electrical and thermal connection interfaces. The package should also provide compliance with safety standards, such as voltage creepage and clearance distances.

Generally speaking, power packages can be categorized as either a discrete package, typically housing a single device (but can include two), or a power module, housing multiple devices. Power modules may place multiple devices in parallel and arrange them into various circuit topologies. As an example, a single switch position package that houses one device would be categorized as discrete, and one that houses multiple devices in parallel (to increase output current) would be considered a power module.

Packages conventionally use, but are not limited to, some combination of the following components, each providing multiple functions. These are summarized in the following table. The terms used in this disclosure, unless otherwise indicated, follow the definitions outlined in Table 1 below.

TABLE 1
Definitions

| Item | Description |
|---|---|
| Power | Controllable switches MOSFET, IGBT, and the like |
| Device(s) | and Diodes |
| Substrate, | Layered metal and ceramic for high current electrical |
| Power | interconnection, high voltage isolation, high thermal |
| | conductivity, coefficient of thermal expansion (CTE) |
| | matching, and external thermal interface |
| Substrate, | Layered Printed Circuit Board (PCB), layered metal and |
| Signal | ceramic, thick film, and the like for high frequency |
| | electrical interconnection and high voltage isolation |
| Terminal, | Metal contact for high current external connection and |
| Power | internal interconnection |
| Terminal, | Metal contact or connector for high frequency external |
| Signal | connection and internal interconnection |
| Lead Frame | Metal contact strip for high current external connection |
| | and internal interconnection; Contacts are joined |
| | together on a single sheet, often with multiple products |
| | per sheet, and are processed as an array and then |
| | formed and singulated |
| Base Plate | Metal or composite material for mechanical structure, |
| | high thermal conductivity, coefficient of thermal |
| | expansion (CTE) matching, and external thermal |
| | interface |
| Device | Solder, adhesive, or sintered metal, and the like for |
| Attach | mechanical structure, high current interconnection, |
| | and high thermal conductivity |
| Terminal | Solder, adhesive, sintered metal, laser weld, ultrasonic |
| Attach | weld, and the like for mechanical structure, high |
| | current interconnection, and high thermal conductivity |
| Substrate | Solder, adhesive, or sintered metal, and the like for |
| Attach | mechanical structure and high thermal conductivity |
| Interconnection | Conductive element forming an electrical connection |
| | between one electrical node and another |
| Wire Bonds, | Ultrasonically or thermosonically bonded large diameter |
| Power | wire, ribbon, and the like for high current electrical |
| | interconnection |
| Wire Bonds, | Ultrasonically or thermosonically bonded small diameter |
| Signal | wire, ribbon, and the like for low current electrical |
| | interconnection |
| Case/Housing | Injection molded case and lid, providing mechanical |
| | structure, high voltage isolation, and acting as a |
| | well for the encapsulation material |
| Mold | Transfer or compression molded epoxy molding |
| Compound | compound (EMC) for mechanical structure, high |
| | voltage isolation, coefficient of thermal expansion |
| | (CTE) matching, and low humidity absorption |
| Encapsulation | Soft, flexible silicone or similar encapsulation |
| | material for high voltage isolation, and low humidity |
| | absorption |
| Temperature | Passive or active element that can be used to monitor |
| Sensor | internal temperatures |
| Signal | Resistors, capacitors, surface mount components, |
| Circuitry | sensors, and the like for stabilization of the dynamic |
| | switching performance of the devices or for other |
| | internal circuit requirements, such as active |
| | miller clamping, etc. |

Some typical design requirements for power device packages include high power density (small package size), high current, high voltage, high temperature operation, low thermal resistance, low stray inductance, fast and clean switching, high efficiency through low on-resistance, high efficiency through high speed switching, thoughtful external terminal layout for effective interconnection, compliance with creepage and clearance standards, moisture sensitivity level (MSL) compliance, and low cost.

A power semiconductor device is typically vertical, meaning power flows from the backside to the topside of the chip (or vice versa). While there are many types of power devices where this technique applies, a MOSFET will be used for the purposes of explanation and illustration.

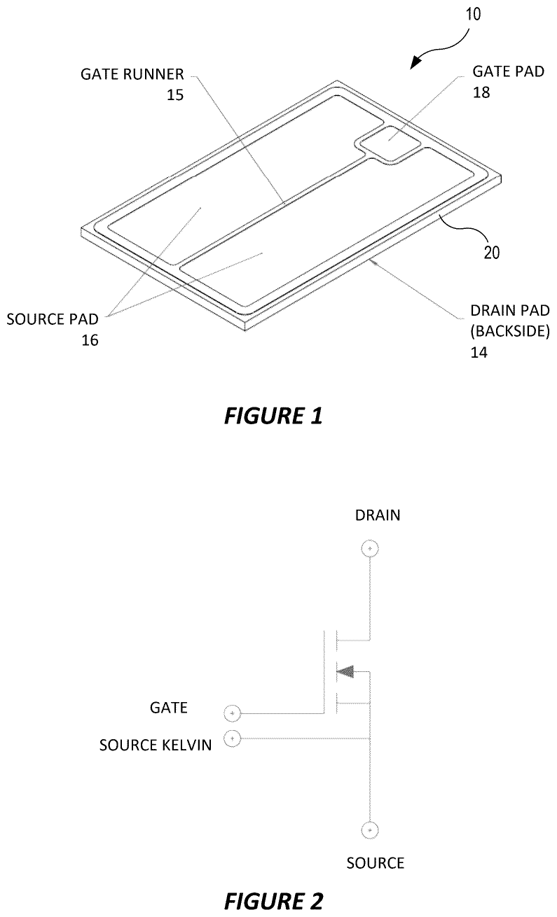

A power MOSFET is a three-terminal device: (1) gate, (2) source, and (3) drain. Often an additional kelvin connection to the source terminal is made to optimize switching performance to isolate the power and signal loops. The gate and source are located on what will be referred to as the device topside, while the drain is located on the device backside. The high current path flows from the drain to source or source to drain, through the area of the device. An example MOSFET device is depicted in FIG. 1, and an example MOSFET circuit element is depicted in FIG. 2.

Referring to FIGS. 1 and 2, a MOSFET device 10 generally includes source, gate and drain terminals. The source terminal is connected to a pair of source pads 16 on the front or top side of a semiconductor die 20, and the gate terminal is connected to a gate pad 18 on the front or top side of the die 20. A gate runner 15 extends from the gate pad 18 and distributes the gate signal across the die 20. The drain terminal is connected to a drain pad 14 on the back side of the die 20.

The topside and backside metallizations that form the source pads 16, the gate pad 18 and the drain pad 14 generally include stack of metals to provide a variety of functions, such as ohmic contact, diffusion barrier, seed layers for plating or adhesion, and a capping bonding layer. The topside bonding layer is generally the thickest and is designed to be metallurgically compatible with the desired topside interconnection method. For example, the topside bonding layer may be aluminum to be most compatible with aluminum wire bonding or copper to be compatible with copper wire bonding. The backside metallization is also a stack of metals serving similar functions. Backside attaches tend to be soldered, brazed, or sintered, rather than connected to wire bonds. The thickness of each layer is generally selected based on what is practical and cost effective to fabricate, what operating conditions are expected, and what performance requirements must be met.

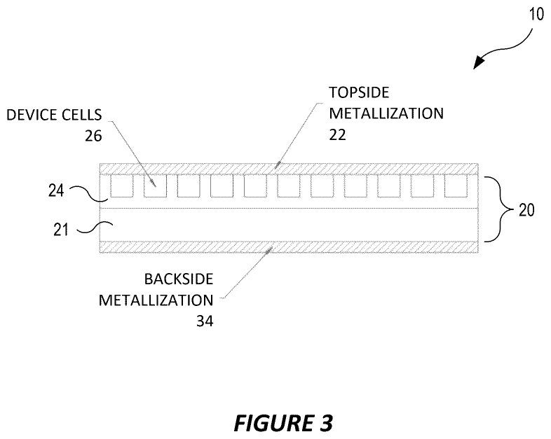

While a power semiconductor device operates as a single device, the physical chip layout is a large array of paralleled device ‘cells’ interconnected through the topside metallization and other functional layers. This is illustrated in FIG. 3 showing a sectional view of a power semiconductor device 10 including a substrate 21 and an epitaxial layer 24 in which a plurality of device cells 26 are formed. The power semiconductor device 10 may, for example, be a MOSFET device. A backside metallization 34 is formed on the back, or bottom side of the die 20, and a topside metallization 22 is formed on the front, or top side of the die 20.

Note that there are many more features and functional layers than depicted in FIG. 3 for simplicity, and the layers are not-to-scale to show detail. Device cells 26 are paralleled through the topside source metallization 22. The bulk of the semiconductor material is used for voltage isolation, with the backside metallization 34 providing electrical contact to the drain. Current flows vertically through the device from the part of the topside metallization 22 forming the source to the backside metallization 34 forming the drain.

In many cases, only a portion of the source pad 16 can be used for interconnection through wire bonds or ribbons. Hence, current must spread from these sites out towards the device cells 26. To effectively obtain the most performance out of the device 10, each of these cells 26 should be fully utilized by carrying as much current as possible. Accordingly, distributing the current from the interconnection sites to each and every cell 26 is important for full device utilization. Distributing current equally among the cells also helps to spread heat evenly across the device.

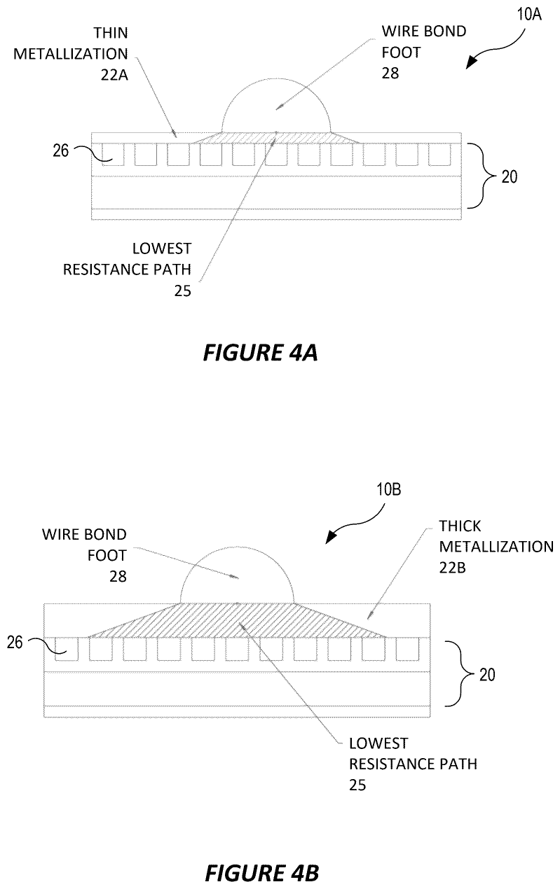

Using thicker metal may reduce the sheet resistance of the topside metallization 22, and may provide more cross sectional area through which current can readily spread. Increasing the thickness of the topside metallization layer 22 may allow for more cells to access a low resistance, efficient path to the input and output sites for current flow. This buffering effect may reduce high current concentrations and/or may reduce localized heating at the bonding interfaces. FIGS. 4A and 4B depict the buffering effect for thin (FIG. 4A) topside metallizations 22A and thick (FIG. 4B) topside metallizations 22B. Note that the device structure and scale of the image are used for description purposes and are not true to structure or scale for an actual device and package. A wire bond foot 28 is provided on the topside metallizations 22A, 22B, and current from the wire bond foot 28 flows into the die 20 via a lowest resistance path 25.

With a thin metallization 22A, there is limited room to laterally spread current and the resulting heat at the interface. These localized high current and heat densities can act to stress and weaken the interface. A thicker metallization 22B helps to buffer the current and heat to better distribute the energy away from the interfaces and evenly towards the device cells 26.

The application of a thicker topside metal may also improve device robustness for more aggressive interconnection methods. For example, copper wire is substantially harder than aluminum and could cause damage to the sensitive device during the wire bonding process. Thicker metals can buffer out the energy applied to form the metallurgical bonds, and a ‘cushioning’ effect adding resilience and wider process windows. Thus, it may be preferable for the thicker topside metal 22A, 22B to improve the performance and bondability of copper wires. Moreover, due to the high conductivity of copper, the use of copper in the topside metal 22A, 22B can enable the use of fewer wire bonds, or may allow higher currents for a given number of wire bonds. The use of thick topside metal may also accommodate larger wire bond footprints, which can allow for more current.

While there are numerous benefits to thicker metallization layers, there are also many processing challenges. For example, there is a large coefficient of thermal expansion (CTE) imbalance between the semiconductor wafer and the metal layers. As the wafer experiences exposures to high temperatures during processing, the metal and semiconductor expand and contract at different rates, creating thermal stress. These thermal stresses can manifest as warpage of the wafer once cooled.

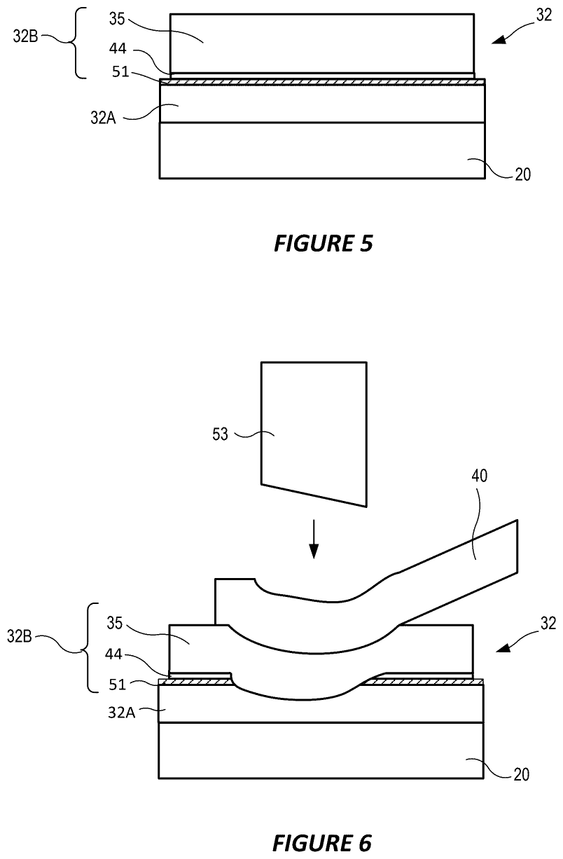

FIG. 5 illustrates a topside metal stack 32 that forms a bond pad on a semiconductor device. In particular, the metal stack 32 includes two primary layers, a first metal layer 32A formed on a semiconductor die 20 and a second metal layer 32B on the first metal layer 32B. The second metal layer 32B may be thicker than the first metal layer 32A.

The second metal layer 32B includes a barrier layer 51 on the first metal layer 32B, a seed layer 44 on the barrier layer 51 and a bond layer 35 on the seed layer 44. Additional layers may be provided in addition to those shown in FIG. 5. The outer edges of the seed layer 46 and/or bond layer 35 may not extend all the way to the outer edge of the barrier layer 51. This may reduce the possibility of edge diffusion from the seed layer 44 and/or the bond layer 35 into the semiconductor die 20.

The second metal layer 32B contacts the first metal layer 32A of the metal stack 32 over a two-dimensional area defined by the peripheral shape of the second metal layer 32B, referred to herein as the “footprint” of the second metal layer 32B.

Barrier metal layers are commonly used under primary metallization layers in discrete power and in integrated circuit technologies, both in silicon and in wide bandgap (WBG) technologies, to obstruct the primary metallization, or a constituent element in the primary metallization, from diffusing into other layers. For example, a TiN layer is commonly used under Tungsten (W) filled contacts to prevent tungsten from diffusing into silicon or WBG materials where it can cause lattice damage, potentially resulting in leakage current in the device. A TiN layer is also commonly used under Al or AlCu-filled contacts to obstruct Al from diffusing into the underlaying substrate and to obstruct Cu from diffusing into metal-oxide semiconductor field effect transistor (MOSFET) or complementary MOS (CMOS) gate oxides where it can cause gate oxide failure, potentially resulting in a reduction in lifetime of the device. In technologies where Cu is a primary metallization, a TiW or TaN or TiN layer may be used under the Cu layer to prevent Cu migration into underlying oxides.

A barrier layer 51 may be relatively thin compared to the first metal layer 32A and/or the bond layer 50. For example, the barrier layer may be formed by a deposition technique such as sputtering, and may have a thickness of about 10 nm to about 500 nm. Nitrided barrier layers can be as thin as 10 nm, while non-nitrided barrier layers can be as thick as 500 nm.

FIG. 6 illustrates forming a wire bond on a bond pad, such as the bond pad formed by the metal stack 32 shown in FIG. 5, on a semiconductor device. To form the wire bond, an end of a thin bond wire 40 is brought into proximity or contact with the bond layer 35 of the metal stack 32. The bond wire 40 may include a metal such as gold, aluminum or copper having a high electrical conductivity. In a process referred to as “wedge bonding,” a wedge-shaped bonding tool 53 is used to press the end of the bond wire 40 against the bond layer 35, and energy is imparted to the bond wire 40 and the bond layer 35 in the form of heat energy, thermosonic energy or mechanical energy. For example, the bonding tool 53 may apply ultrasonic vibration to the bond wire 40 and the bond layer 35, which generates friction and localized heating at the interface between the bond wire 40 and the bond layer 35.

The pressure applied by the bonding tool 53 and the heat applied to the interface cause the atoms of the bond wire 40 and the bond pad 35 to alloy and form intermetallic compounds, creating a physical connection between the bond wire 40 and the bond layer 35.

During this process, as illustrated in FIG. 6, the bond layer 35 may be pressed down into the first metal layer 32A beneath the bond layer 35 due to the pressure and heat applied to the bond layer 35. Moreover, because the bond layer 35 is formed of a relatively soft metal such as copper, the force applied to the bond layer 35 may not be distributed evenly across the entire footprint of the second metal layer 32B, but rather may be concentrated beneath the bonding tool 53.

Because the barrier layer 51 is relatively thin, this may cause the metal of the bond layer 35 to push into and intermix with the metal of the first metal layer 32A. The first metal layer 32A may include a material such as aluminum or an aluminum copper alloy. For example, the first metal layer 32A may be Al 100%, or Al 99.5%-Cu 0.5%, or Al 99%-Cu 1%, or Al 98%-Cu 2%, or Al 98.5%-Cu 0.5%-Si 1%, or similar. However, it will be noted that note that none of these alloys increase the hardness of the metal layer enough to prevent damage from a heavy Cu wire-bond.

The introduction of metal from the bond layer 35 into the first metal layer 32A may be detrimental to the operation of the semiconductor device, because the atoms from the bond layer 35 may undesirably penetrate into the semiconductor layers of the semiconductor die 20. In particular, copper atoms used to form the bond layer 35 may harm the semiconductor device formed in the semiconductor die 20. Some embodiments described below are provided to help avoid or reduce the penetration of the bond layer 35 through the barrier layer 51 and into the first metal layer 32A during a process of forming a wire bond on the bond layer 35.

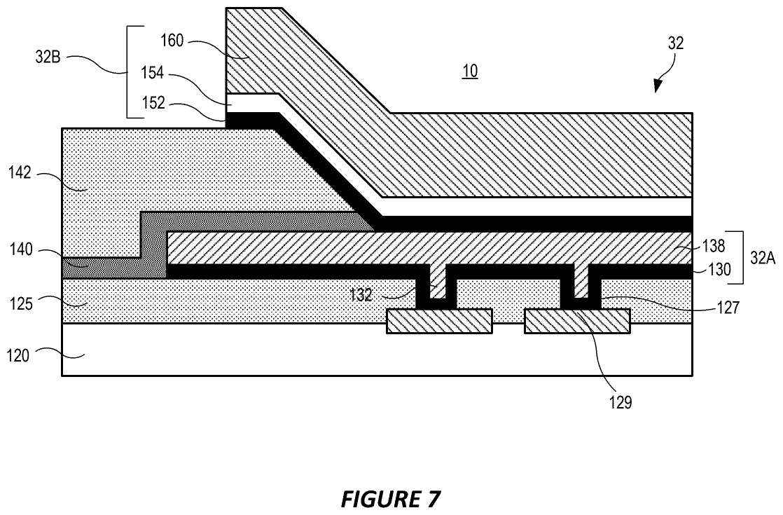

FIG. 7 illustrates a detail of an end portion of a conventional metal stack of a semiconductor device 10. An interlayer dielectric layer 125 is formed on a semiconductor die 120. The semiconductor die may include silicon carbide, such as silicon carbide having a 2H, 4H, 6H, 3C or 15R polytype. Ohmic contacts 129 are formed on the semiconductor die 120. The ohmic contacts 129 may, for example, be source contacts, gate contacts or other contacts of the semiconductor device 100. The ohmic contacts 129 may, for example, be silicide regions that at least partially extend into the semiconductor die 120. A metal stack 32 including a first metal layer 32A and a second metal layer 32B is formed on the interlayer dielectric layer 125. The interlayer dielectric layer 125 includes one or more vias 127 therethrough. Portions 132 of the first metal layer 32A extend through the vias 127 to conductively contact the ohmic contacts 129.

A first metal layer 32A including an optional intermediate layer 130 and a capping layer 138 on the intermediate layer 130 is formed on the semiconductor die 120. The first metal layer 32A may include a material such as aluminum or an aluminum copper alloy. For example, the first metal layer 32A may be Al 100%, or Al 99.5%-Cu 0.5%, or Al 99%-Cu 1%, or Al 98%-Cu 2%, or Al 98.5%-Cu 0.5%-Si 1%, or similar. The intermediate layer 130 may include a material such as titanium (Ti), tungsten (W), tantalum (Ta), TaN, TiN, and/or TiW, which are capable of blocking or impeding the diffusion of metals such as copper, silver, nickel or aluminum that may be harmful to the semiconductor die 120. The capping layer 138 may include a highly conductive metal, such as copper, aluminum, or an alloy thereof.

The edges of the first metal layer 32A are protected by a protective structure that may include a passivation layer 140 that is on the interlayer dielectric layer 125 and that extends onto end portions of the first metal layer 32A.

In some embodiments, the passivation layer 140 may not be present. If the passivation layer 140 is not present, a protective layer 142 of, for example, polyimide, may serve as both passivation and mechanical/environmental protection. The protective layer 142 also provides the seal for Cu metal migration.

Typically, the passivation layer 140 may be provided when the first metal layer 32A is Al (or AlCu or AlSiCu), and the passivation layer 140 is not used when the first metal layer 32A is Cu. However, it is possible to omit the passivation layer 140 even if the first metal is Al or AlCu or AlSiCu.

When present, the passivation layer 140 may include a material such as silicon oxide, silicon nitride, silicon oxynitride, etc., that is provided to protect underlying structures from moisture, contamination, and mechanical damage. A protective layer 142 of a material such as polyimide is provided on the passivation layer 140. The protective layer 142 may provide additional mechanical and/or environmental protection for the underlying device structure, as well as providing a layer that can be planarized to facilitate subsequent processing steps.

An opening is formed in the passivation layer 140 and the protective layer 142 to expose the first metal layer 32A, and the second metal layer 32B is formed in the opening to contact the first metal layer 32A. The second metal layer 32B may include a barrier layer 152, a seed layer 154 and a bond layer 160. The barrier layer 150 may include a material such as titanium (Ti), tungsten (W), tantalum (Ta), TaN, TiN, and/or TiW. The seed layer 154 may include a thin layer of material, such as copper, that can act as a seed for forming a thick copper bond layer 160 thereon. The barrier layer 152 and the seed layer 154 may be formed by a deposition technique, such as sputtering, that produces relatively thin layers. For example, the barrier layer 152 may have a thickness of about 50 nm to 500 nm. In some embodiments, the barrier layer 152 may have a thickness of about 100 nm to 400 nm, and in some embodiments about 200 nm to 300 nm.

Because of the provision of a seed layer 154, the bond layer 160 may be formed by a process, such as electroplating, that can quickly form thicker layers of metal on a substrate.

As noted above, when forming a wire bond to a bond layer of a metal stack using a bonding technique such as wedge bonding, it is possible to cause the bond layer to be undesirably pushed through a barrier layer and into an underlying metal layer due to the heat and/or pressure applied to the bond layer during the bonding process. In particular, the use of a wedge bonding tool may cause pressure to be applied to a localized portion of the bond layer, causing it to deform and push through the barrier layer.

Some embodiments provide a structural support layer beneath or within a bond layer, where the structural support layer is formed of a metal having a greater hardness than the metal of the bond layer. While not being bound by a particular theory, it is believed that the presence of a structural support layer beneath and/or within a bond layer may cause force applied to the bond layer during the wire bonding process to be distributed over a larger area of the bond layer, thereby reducing or avoiding the bond layer being pushed though the barrier layer during a wire bonding process. In particular, in some embodiments, a structural support layer provided within or beneath a bond layer may have a sufficient hardness and/or thickness to obstruct or prevent the bond layer from being pushed through an underlying barrier layer during a wire bonding process.

Metal hardness is an intrinsic property of metals that depends on the composition of the metal, i.e., what element or alloys are included in the metal. The hardness of a metal may be affected by heat treatment and other processing conditions used to form or shape the metal.

Metal hardness may be measured according to different measurement scales, including the Vickers hardness scale, the Brinell hardness scale and the Mohs hardness scale. According to these scales, copper and aluminum are rated as soft metals. For example, the Mohs hardness of copper, aluminum, nickel, tungsten, tantalum, platinum and titanium are shown in Table 1 along with their electrical and thermal conductivities.

TABLE 1
Metal Properties

| | Mohs | Electrical Conductivity | Thermal Conductivity |
|---|---|---|---|
| Metal | Hardness | (IACS) | (W/m-K) |
| Tungsten | 7.5 | 31% | 173 |
| Tantalum | 6.5 | 13% | 57.5 |
| Titanium | 6 | 3.1% | 21.9 |
| Nickel | 4 | 22% | 90.9 |
| Platinum | 3.5 | 15.9% | 71.6 |
| Copper | 3 | 100% | 401 |
| Aluminum | 2.75 | 61% | 237 |

As shown in Table 1, aluminum is rated about 2.75 and copper is rated about 3 on the Mohs hardness scale. Metals such as nickel (Mohs hardness: 4), tantalum (Mohs hardness 6.5), Titanium (Mohs hardness: 6) and Tungsten (Mohs hardness 7.5) are all harder than aluminum or copper. Titanium nitride and tantalum nitride are extremely hard, having rankings greater than 8 on the Mohs hardness scale.

However, materials that are not as electrically or thermally conductive as copper or aluminum may be less desirable for use as thick metal layers on a semiconductor device. For example, the electrical conductivities of the metals listed in Table 1 are shown in terms of the International Annealed Copper Standard (IACS), which is a standard used to compare the electrical conductivity of different materials, with pure annealed copper set as the reference at 100%. The percentage IACS value of a material indicates how its electrical conductivity compares to that of pure copper. For example, as shown in Table 1, aluminum has a conductivity of 61% IACS, which means it has 61% of the electrical conductivity of pure annealed copper.

As seen in Table 1, nickel, tungsten, platinum, tantalum, and titanium are significantly less electrically conductive than copper and aluminum, with titanium having the lowest electrical conductivity in this group at about 3.1%. The total contribution of a metal layer in a bond pad to the contact resistance of the bond pad depends on the thickness and electrical conductivity of the metal. In particular, as the thickness of a metal layer in a bond pad increases, its contribution to the contact resistance of the bond pad increases.

Thermal conductivity is also an important property of metals in a metal stack for a semiconductor bond pad. Copper and aluminum have the highest thermal conductivities shown in Table 1, at about 401 and 237 W/m-K respectively. Tungsten and nickel have good thermal conductivity at about 173 and 90.9 W/m-K respectively. Titanium, platinum and tantalum have low thermal conductivity.

Some particular embodiments may employ nickel as a structural support layer. Nickel (Ni) is a stronger material than copper and aluminum and can act as a support/buffer layer that can absorb the strong forces of the heavy copper wire bonds while having acceptable thermal and electrical conductivity to be included in a bond pad metal stack. Nickel is also suitable for use in devices intended for high temperature operation (e.g., greater than 200° C.).

Providing a nickel layer between the first and second metal layers can reduce deformation of the lower metal layer and thus protect the barrier layer therebetween. Moreover, in some embodiments described below, multiple layers of nickel and copper, that is, Ni—Cu—Ni—Cu composite layers may be provided on top of the lower metal layer to better absorb or spread out the forces experienced during the formation of heavy copper wire-bonds.

The provision of a structural support layer as described herein may also reduce the mechanical stress experienced by the underlying die during the wire bonding process than a single layer of nickel and copper. Thus, the use of nickel as a structural support layer may not only protect the lower metal layer from deforming but may also increase the overall robustness of the device.

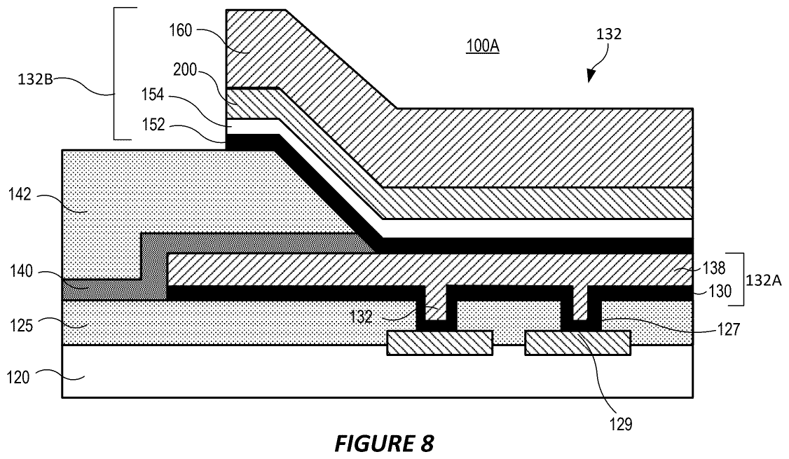

FIG. 8 illustrates a detail of an end portion of a metal stack 132 of a semiconductor device 100A according to some embodiments. The metal stack 132 shown in FIG. 8 is similar to the metal stack 32 shown in FIG. 7. In particular, the metal stack 132 includes a first metal layer 132A that includes an optional barrier layer 130 and a capping layer 138, and a second metal layer 132B on the first metal layer 132A. The second metal layer 132B includes a barrier layer 152 and a seed layer 154 on the barrier layer, and a bond layer 160 on the seed layer 154 on which a wire bond may be formed. Differences between the metal stack 132 of FIG. 8 and the metal stack 32 of FIG. 7 will be described in detail below.

In the device 100A, the second metal layer 132B further includes a structural support layer 200 between the seed layer 154 and the bond layer 160. The structural support layer 200 may have a hardness and/or thickness that is selected to obstruct or prevent the bond layer 160 from being pushed through the underlying barrier layer 152 and into the first metal layer 132A during a wire bonding process.

In particular, the bond layer 160 includes a metal having a first hardness and the structural support layer 200 includes a metal having a second hardness that is greater than the first hardness. For example, the bond layer 160 may include copper, and the structural support layer 200 may include a metal having a hardness greater than copper, such as nickel, tungsten, titanium, platinum, tantalum, TiN, and/or TaN. Because the structural support layer 200 contributes a significant thickness to the metal stack 132, it is important that the structural support layer 200 be formed from a material having good electrical and thermal conductivity. For example, the structural support layer 200 should be formed from a material having an electrical conductivity of at least about 20% IACS and a thermal conductivity of at least about 50 W/m-K.

The first metal layer 132A may include a metal having a third hardness that is less than the second hardness of the structural support layer 200. For example, the capping layer 138 of the first metal layer 132A may include aluminum, copper or an alloy of aluminum and copper. In particular, the first metal layer 132A may include a material such as aluminum or an aluminum copper alloy. For example, the first metal layer 132A may be Al 100%, or Al 99.5%-Cu 0.5%, or Al 99%-Cu 1%, or Al 98%-Cu 2%, or Al 98.5%-Cu 0.5%-Si 1%, or similar.

The second metal layer 132B contacts the first metal layer 132A, through the underlying seed layer 154 and barrier layer 152, over the footprint of the second metal layer 132B. The thickness and second hardness of the structural support layer 200 are selected to distribute a force applied to the second metal layer 132B during attachment of a wire bond to the bond layer 160 more evenly across the footprint of the second metal layer 132B.

The structural support layer 200 may have a thickness of between about 1 micron and 5 microns. In some embodiments, the structural support layer 200 has a thickness of between about 1.5 microns and 3 microns, and in some embodiments, the structural support layer 200 has a thickness of about 2 microns. In particular, the structural support layer 200 may have a thickness that is greater than a thickness of the barrier layer 152, and, along with the bond layer 160, may be formed using a process, such as electroplating, that enables the formation of thicker layers (e.g., greater than about 1 micron).

The second metal layer 132B may have an overall thickness of about 5 microns to about 50 microns. In some embodiments, the second metal layer 132B may have a thickness of about 10 microns to 40 microns, and in some embodiments about 20 microns to 30 microns.

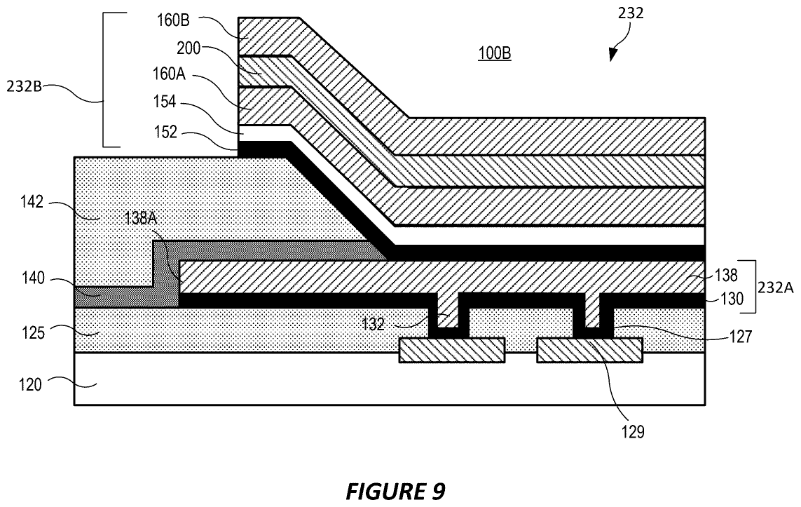

FIG. 9 illustrates a detail of an end portion of a metal stack 232 of a semiconductor device 100B according to further embodiments.

The metal stack 232 shown in FIG. 9 is similar to the metal stack 132 shown in FIG. 8. In particular, the metal stack 232 includes a first metal layer 232A that includes an optional barrier layer 130 and a capping layer 138, and a second metal layer 232B on the first metal layer 232A. The second metal layer 232B includes a barrier layer 152 and a seed layer 154 on the barrier layer, and a bond layer 160 on the seed layer 154 on which a wire bond may be formed. Differences between the metal stack 232 of FIG. 9 and the metal stack 132 of FIG. 8 will be described in detail below.

In the device 100B, the second metal layer 232B includes first and second bond layers 160A, 160B on the seed layer 154, and a structural support layer 200 between the first bond layer 160A and the second bond layer 160B. The structural support layer 200 may have a hardness and/or thickness that is selected to spread out force applied to the second bond layer 160B during a wire bonding process, to thereby obstruct or prevent the first bond layer 160A and/or the second bond layer 160B from being pushed through the underlying barrier layer 152 and into the first metal layer 232A during a wire bonding process.

In particular, the first bond layer 160A and the second bond layer 160B include a metal having a first hardness and the structural support layer 200 includes a metal having a second hardness that is greater than the first hardness. For example, the first bond layer 160A and/or the second bond layer 160B may include copper, and the structural support layer 200 may include a metal having a hardness greater than copper, such as nickel, tungsten, titanium, platinum, tantalum, TiN, and/or TaN. Further, the structural support layer 200 may be formed from a material having an electrical conductivity of at least about 20% IACS and a thermal conductivity of at least about 50 W/m-K.

The first metal layer 232A may include a metal having a third hardness that is less than the second hardness of the structural support layer 200. For example, the capping layer 138 of the first metal layer 232A may include aluminum, copper or an alloy of aluminum and copper.

The second metal layer 232B contacts the first metal layer 232A over the footprint of the second metal layer 232B. The thickness and second hardness of the structural support layer 200 are selected to distribute a force applied to the second bond layer 160B of the second metal layer 232B during attachment of a wire bond to the second bond layer 160B more evenly across the footprint of the second metal layer 232B.

The structural support layer 200 may have a thickness of between about 1 micron and 5 microns. In some embodiments, the structural support layer 200 has a thickness of between about 1.5 microns and 3 microns, and in some embodiments, the structural support layer 200 has a thickness of about 2 microns. In particular, the structural support layer 200 may have a thickness that is greater than the thickness of the barrier layer 152, and, along with the bond layer 160, may be formed using a process, such as electroplating.

The second metal layer 232B may have an overall thickness of about 5 microns to about 50 microns. In some embodiments, the second metal layer 232B may have a thickness of about 10 microns to 40 microns, and in some embodiments about 20 microns to 30 microns.

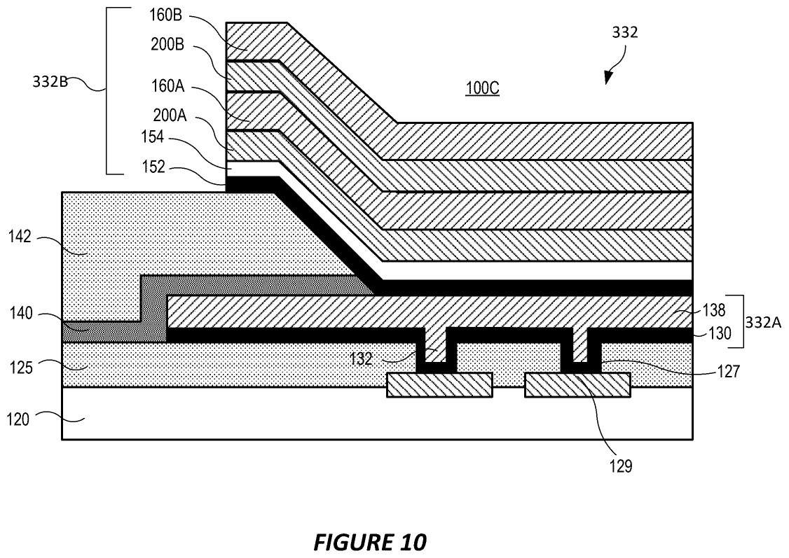

FIG. 10 illustrates a detail of an end portion of a metal stack 332 of a semiconductor device 100C according to further embodiments.

The metal stack 332 shown in FIG. 10 is similar to the metal stack 132 shown in FIG. 8. In particular, the metal stack 332 includes a first metal layer 332A that includes an optional barrier layer 130 and a capping layer 138, and a second metal layer 332B on the first metal layer 332A. The second metal layer 332B includes a barrier layer 152 and a seed layer 154 on the barrier layer. Differences between the metal stack 332 of FIG. 10 and the metal stack 132 of FIG. 8 will be described in detail below.

In the device 100C, the second metal layer 232B includes a plurality of pairs of structural support layers and bond layers sequentially stacked on first metal layer 332A. The device 100C shown in FIG. 10 includes two pairs of structural support layers 200A/200B and bond layers 160A/160B sequentially stacked on first metal layer 332A. Thus, in the device 100A, a first structural support layer 200A is formed on the seed layer 154, a first bond layer 160A is formed on the first structural support layer 200A. A second structural support layer 200B is formed on the first bond layer 160A, and a second bond layer 160B is formed on the second structural support layer 200B. However, it will be appreciated that the device may include more than two pairs of structural support layers 200A/200B and bond layers 160A/160B.

The structural support layers 200A/200B may have a hardness and/or thickness that is selected to spread out force applied to the uppermost bond layer 160B during a wire bonding process, to thereby obstruct or prevent the first bond layers 160A and/or the second bond layer 160B from being pushed through the underlying barrier layer 152 and into the first metal layer 332A during a wire bonding process.

In particular, the first bond layer 160A and the second bond layer 160B include a metal having a first hardness and the first structural support layer 200A and the second structural support layer 200B include a metal having a second hardness that is greater than the first hardness. For example, the first bond layer 160A and/or the second bond layer 160B may include copper, and the first structural support layer 200A and/or the second structural support layer 200B may include a metal having a hardness greater than copper, such as nickel, tungsten, titanium, platinum, tantalum, TiN, and/or TaN. Further, the first and second structural support layers 200A/200B may be formed from a material having an electrical conductivity of at least about 20% IACS and a thermal conductivity of at least about 50 W/m-K.

The first metal layer 332A may include a metal having a third hardness that is less than the second hardness of the first and second structural support layers 200A/200B. For example, the capping layer 138 of the first metal layer 332A may include aluminum, copper or an alloy of aluminum and copper.

The thickness and second hardness of the first and second structural support layers 200A/200B are selected to distribute a force applied to the second metal layer 332B during attachment of a wire bond to the second metal layer 332B more evenly across the footprint of the second metal layer 332B.

Each structural support layer 200A/200B may have a thickness of between about 1 micron and 5 microns. In some embodiments, each of the first and second structural support layers 200 may have a thickness of between about 1.5 microns and 3 microns, and in some embodiments, each of the structural support layers 200A/200B may have a thickness of about 2 microns. In particular, each of the structural support layers 200A/200B may have a thickness that is greater than a thickness of the barrier layer 152, and, along with the bond layers 160A/160B may be formed using a process, such as electroplating.

The second metal layer 332B may have an overall thickness of about 5 microns to about 50 microns. In some embodiments, the second metal layer 332B may have a thickness of about 10 microns to 40 microns, and in some embodiments about 20 microns to 30 microns.

While the above-described power semiconductor devices and the other devices described herein are shown as being silicon carbide-based semiconductor devices, it will be appreciated that embodiments of the present inventive concepts are not limited thereto. Instead, the semiconductor devices may comprise any wide bandgap semiconductor that is suitable for use in power semiconductor devices including, for example, gallium nitride-based semiconductor devices, gallium nitride-based semiconductor devices and II-VI compound semiconductor devices.

The inventive concepts have been described above with reference to the accompanying drawings, in which embodiments of the inventive concepts are shown. This inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present inventive concepts.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the inventive concepts.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present inventive concepts may include additional and/or intervening layers, structures, or elements, and/or particular layers, structures, or elements may be deleted. Although a few exemplary embodiments of the inventive concepts have been described, those skilled in the art will readily appreciate that many modifications are possible in the exemplary embodiments without materially departing from the novel teachings and advantages of the inventive concepts. Accordingly, all such modifications are intended to be included within the scope of the inventive concepts as defined in the claims. Therefore, it is to be understood that the foregoing is illustrative of the present inventive concepts and is not to be construed as limited to the specific embodiments disclosed, and that modifications to the disclosed embodiments, as well as other embodiments, are intended to be included within the scope of the appended claims. The inventive concepts are defined by the following claims, with equivalents of the claims to be included therein.

1. A semiconductor device, comprising:
a semiconductor die; and
a bond pad on the semiconductor die, the bond pad comprising a bond layer, and a structural support layer between the bond layer and the semiconductor die;
wherein the bond layer has a first hardness and the structural support layer has a second hardness that is greater than the first hardness.

2. The semiconductor device of claim 1, wherein the bond pad comprises:
a barrier layer, wherein the structural support layer is between the barrier layer and the bond layer; and
a first metal layer, wherein the barrier layer is on the first metal layer between the first metal layer and the bond layer, wherein the first metal layer comprises a metal having a third hardness that is less than the second hardness.

3. The semiconductor device of claim 2, wherein the structural support layer has a thickness and contacts the first metal layer over a footprint of the structural support layer, wherein the thickness and second hardness of the structural support layer are selected to distribute a force applied to the bond layer during attachment of a wire bond to the bond layer across the footprint of the structural support layer on the first metal layer.

4. The semiconductor device of claim 2, further comprising:
a seed layer on the barrier layer, wherein the seed layer is between the barrier layer and the structural support layer.

5. The semiconductor device of claim 4, wherein the seed layer comprises a same metal as the bond layer.

6. The semiconductor device of claim 1, wherein the bond layer comprises copper, and wherein the structural support layer comprises a metal having a greater hardness than copper.

7. The semiconductor device of claim 6, wherein the structural support layer comprises nickel, tungsten, platinum, titanium, tantalum, TiN, and/or TaN.

8. The semiconductor device of claim 1, wherein the structural support layer has a thickness of between about 1 micron and 5 microns.

9. The semiconductor device of claim 1, wherein the structural support layer has a thickness of between about 1.5 microns and 3 microns.

10. The semiconductor device of claim 1, wherein the structural support layer has a thickness of about 2 microns.

11. The semiconductor device of claim 2, wherein the bond layer comprises a first bond layer, the semiconductor device further comprising a second bond layer, wherein the second bond layer is between the structural support layer and the barrier layer.

12. The semiconductor device of claim 11, wherein the structural support layer comprises a first structural support layer, the semiconductor device further comprising a second structural support layer, wherein the second structural support layer is between the second bond layer and the barrier layer, wherein the second structural support layer has a third hardness that is greater than the first hardness.

13. The semiconductor device of claim 1, wherein the semiconductor device comprises a metal stack including a plurality of pairs of bond layers and structural support layers, wherein a top layer of the metal stack comprises one of the bond layers of the plurality of bond layers.

14. The semiconductor device of claim 1, wherein the semiconductor die comprises silicon carbide.

15. The semiconductor device of claim 1, wherein the bond layer and the structural support layer comprise electroplated layers.

16. A semiconductor device, comprising:
a semiconductor die; and
a bond pad on the semiconductor die, the bond pad comprising a seed layer, a first bond layer on the seed layer, a structural support layer on the first bond layer, and a second bond layer on the structural support layer;
wherein the bond layer has a first hardness and the structural support layer has a second hardness that is greater than the first hardness.

17. The semiconductor device of claim 16, further comprising a second structural support layer between the seed layer and the first bond layer, wherein the second structural support layer has a third hardness that is greater than the first hardness.

18. The semiconductor device of claim 16, wherein the first and second bond layers comprise copper and the structural support layer comprises nickel, tungsten, platinum, titanium, manganese, TiN, and/or TaN.

19. The semiconductor device of claim 16, wherein the bond pad comprises:
a first metal layer, wherein the seed layer is between the first metal layer and the bond layer.

20. A semiconductor device, comprising:
a semiconductor die; and
a bond pad on the semiconductor die, the bond pad comprising a seed layer, and two or more support/bond layer pairs on the seed layer, wherein each support/bond layer pair comprises a structural support layer and a bond layer on the structural support layer, wherein each bond layer in a support/bond layer pair has a first hardness and each structural support layer in a support/bond layer pair has a second hardness that is greater than the first hardness.

21. The semiconductor device of claim 20, wherein each bond layer comprises copper and each structural support layer comprises nickel, tungsten, platinum, titanium, tantalum, TiN, and/or TaN.

22. The semiconductor device of claim 20, further comprising:
a barrier layer, wherein the seed layer is between the barrier layer and the plurality of support/bond layer pairs.

23. The semiconductor device of claim 20, wherein the bond pad comprises:
a first metal layer, wherein the seed layer is between the first metal layer and the bond layer.
